(19) United States
(12) Patent Application Publication
(10) Pub. No.: US 2019/0123659 A1
(43) Pub. Date: Apr. 25, 2019

(54) Power Converter

(71) Applicant: Hitachi Automotive Systems, Ltd., Hitachinaka,-shi, Ibaraki (JP)

(72) Inventors: Yutaka OKUBO, Hitachinaka (JP); Tokihito SUWA, Hitachinaka (JP); Yusuke TAKAGI, Hitachinaka (JP)

(21) Appl. No.: 16/096,564

(22) PCT Filed: Mar. 2, 2017
(86) PCT No.: PCT/JP2017/008301

§ 371 Date: Oct. 25, 2018

(30) Foreign Application Priority Data
Apr. 28, 2016 (JP) 2016-090042

(51) Int. Cl. H02M 7/00; H02M 7/48; H01L 23/473; H01L 23/367; H05K 7/20

(52) U.S. Cl. CPC H02M 7/003; H02M 7/48; H01L 2224/33; H01L 23/367; H05K 7/20927; H01L 23/473

(57) ABSTRACT

Reliability of a power converter is improved while suppressing an increase in size and an increase in cost of the power converter. A power converter according to the present invention includes a power semiconductor module and a flow path forming body which contains the power semiconductor module and forms a flow path through which a refrigerant flows. In the flow path forming body, a first opening which communicates one surface of the flow path forming body with the flow path is formed, and in the power semiconductor module, a first sealing surface which is formed along an insertion direction of the power semiconductor module into the flow path and faces the flow path forming body and a second sealing surface which is formed along the insertion direction and faces the flow path forming body are formed.

### TECHNICAL FIELD

The present invention relates to a power converter, and particularly, to a power converter used for a hybrid vehicle or an electric vehicle.

### BACKGROUND ART

A power semiconductor module used for a power converter, particularly, a power semiconductor module used for a hybrid vehicle or an electric vehicle is configured so that the power semiconductor module is immersed to a flow path forming body and many surfaces of the power semiconductor module function as cooling surfaces to improve a cooling efficiency (PTL 1).

In a case where such a cooling system is used, a pressure of a refrigerant flowing through a flow path formed in the flow path forming body makes the power semiconductor module be extracted from the flow path forming body and applies a stress to a terminal of the power semiconductor module. Accordingly, reliability of the power converter is deteriorated. To take measures against the deterioration of the reliability, the size and the cost of the power converter may be increased.

### CITATION LIST

### Patent Literature

PTL 1: JP 2014-72939 A

### SUMMARY OF INVENTION

### Technical Problem

An object of the present invention is to improve reliability of a power converter while suppressing an increase in size and an increase in cost of the power converter.

### Solution to Problem

A power converter according to the present invention includes a power semiconductor module and a flow path forming body which contains the power semiconductor module and forms a flow path through which a refrigerant flows. In the flow path forming body, a first opening which communicates one surface of the flow path forming body with the flow path is formed, and in the power semiconductor module, a first sealing surface which is formed along an insertion direction of the power semiconductor module into the flow path and faces the flow path forming body and a second sealing surface which is formed along the insertion direction and faces the flow path forming body are formed.

### Advantageous Effects of Invention

According to the present invention, reliability of a power converter can be improved while suppressing an increase in size and an increase in cost of the power converter.

### BRIEF DESCRIPTION OF DRAWINGS

FIG. 1 is an external perspective view of a power converter 100.

FIG. 2 is an exploded perspective view of the power converter 100 illustrated in FIG. 1.

FIG. 3 is a perspective view of a power semiconductor module 300a according to the present embodiment.

FIG. 4 is a cross-sectional view of the power semiconductor module 300a, assembled to a flow path forming body 200, cut from an arrow direction taken along an A-A cross section illustrated in FIG. 3.

FIG. 5(a) is a diagram for explaining a refrigerant pressure among forces applied to a power semiconductor module 300d in a case where a second sealing member 802 is not provided as a comparative example.

FIG. 5(b) is a diagram for explaining a force, with which the power semiconductor module 300d is extracted from the flow path forming body 200, among the forces applied to the power semiconductor module 300d in a case where the second sealing member 802 is not provided as the comparative example.

FIG. 6(a) is a diagram for explaining a refrigerant pressure among forces applied to the power semiconductor module 300a according to the present embodiment.

FIG. 6(b) is a diagram for explaining a force, with which the power semiconductor module 300a is extracted from the flow path forming body 200, among the forces applied to the power semiconductor module 300a according to the present embodiment.

FIG. 7 is a cross-sectional view in which a fixing plate 500 is provided on the flow path forming body 200.

FIG. 8 is a diagram for explaining a power semiconductor module 300e including a second projecting portion 311.

FIG. 9(a) is a diagram for explaining a refrigerant pressure among forces applied to the power semiconductor module 300e including the second projecting portion 311.

FIG. 9(b) is a diagram for explaining a force, with which the power semiconductor module 300a is extracted from the flow path forming body 200, among the forces applied to the power semiconductor module 300e including the second projecting portion 311.

FIG. 10 is a cross-sectional view of an embodiment in which a flow path wall 201 of the flow path forming body 200 has a tapered shape.

FIG. 11(a) is a diagram for explaining a refrigerant pressure among forces applied to a power semiconductor module 300f in which a flow path side wall 304a has an obtuse angle against a first heat dissipation unit 305a and a second heat dissipation unit 305b.

FIG. 11(b) is a diagram for explaining a force, with which the power semiconductor module 300a is extracted from the flow path forming body 200, among the forces applied to the power semiconductor module 300f in which the flow path side wall 304a has an obtuse angle against the first heat dissipation unit 305a and the second heat dissipation unit 305b.

FIG. 12 is a cross-sectional view for explaining a power semiconductor module 300g having a first terminal 320 and a second terminal 321.

### DESCRIPTION OF EMBODIMENTS

An embodiment for carrying out the present invention will be described below with reference to the drawings.

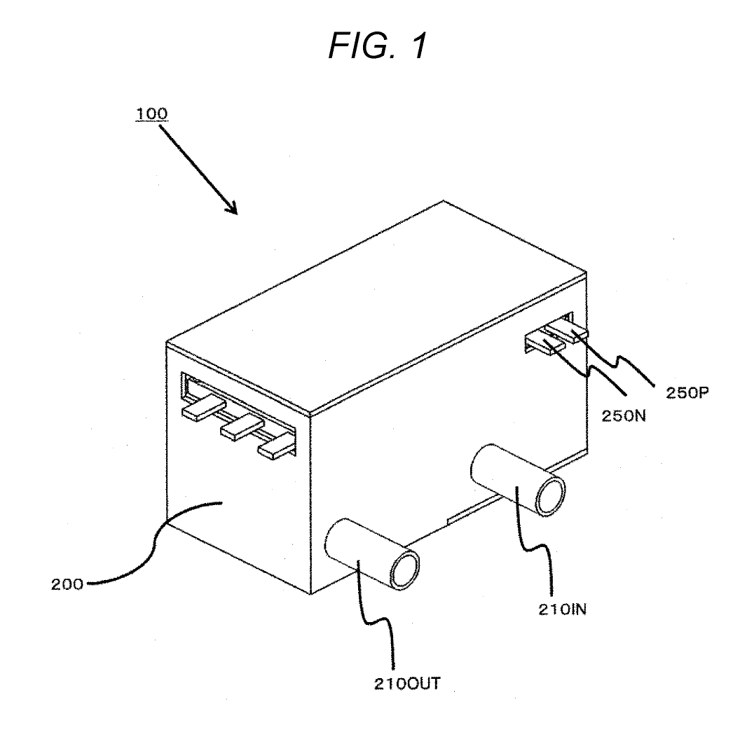

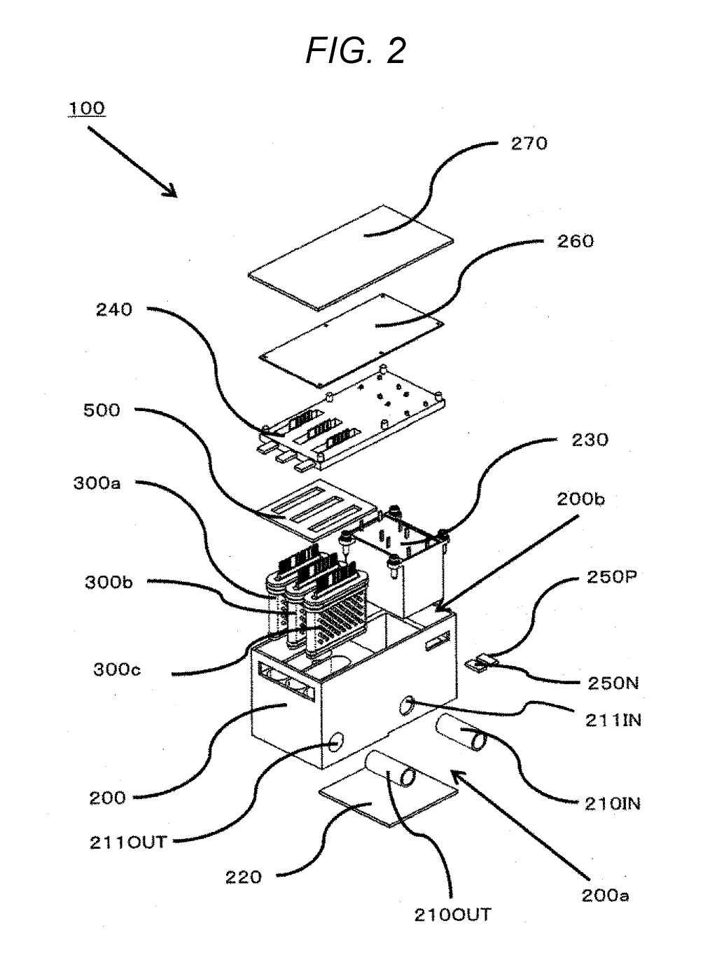

FIG. 1 is an external perspective view of a power converter 100. FIG. 2 is an exploded perspective view of the power converter 100 illustrated in FIG. 1.

Power semiconductor modules 300a to 300c form inverter circuits that respectively output alternating currents of a U phase, a V phase, and a W phase. A capacitor module 230 smooths a direct current transmitted to the power semiconductor modules 300a to 300c.

A bus bar assembly 240 transmits the direct current from the capacitor module 230 to the power semiconductor modules 300a to 300c. The bus bar assembly 240 includes a positive electrode side bus bar, a negative electrode side bus bar, and a molding material for supporting the positive electrode side bus bar and the negative electrode side bus bar. DC input bus bars 250P and 250N electrically connect a battery to the bus bar assembly 240.

A circuit board 260 in the present embodiment includes a control circuit unit which generates a control signal for controlling the power semiconductor modules 300a to 300c and a drive circuit unit which generates a drive signal for driving the power semiconductor modules 300a to 300c. Noted that only one of the control circuit unit and the drive circuit unit may be mounted on the circuit board 260.

A flow path forming body 200 is a box-like rectangular parallelepiped having a pair of short side wall portions and a pair of long side wall portions. The flow path forming body 200 contains the capacitor module 230, the power semiconductor modules 300a to 300c, the bus bar assembly 240, the DC input bus bars 250P and 250N, the circuit board 260, and the like.

It is possible that the flow path forming body 200 only fixes the power semiconductor modules 300a to 300c and that the other components such as the capacitor module 230 is contained in a casing different from the flow path forming body 200.

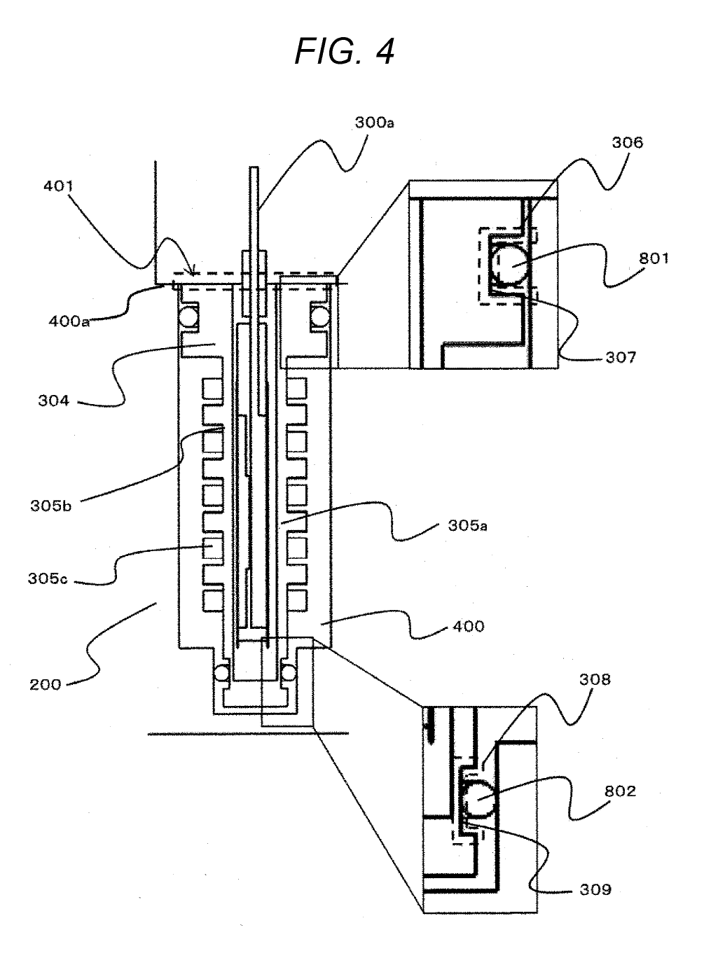

A casing lower cover 220 is assembled to cover a flow path forming body lower surface 200a. As a result, watertightness of a refrigerant flowing through a flow path 400 (refer to FIG. 4) in the flow path forming body 200 is secured. A casing upper cover 270 is assembled to cover a flow path forming body upper surface 200b after the components have been contained in the flow path forming body 200.

A refrigerant inflow pipe 210IN and a refrigerant outflow pipe 210OUT are respectively inserted into a refrigerant inflow port 211IN and a refrigerant outflow port 211OUT of the flow path forming body 200, and the refrigerant is flowed in and out through the refrigerant inflow pipe 210IN and the refrigerant outflow pipe 210OUT.

A fixing plate 500 is fixed to the flow path forming body 200 while having contact with the power semiconductor modules 300a to 300c so that the power semiconductor modules 300a to 300c are not detached from the flow path forming body 200.

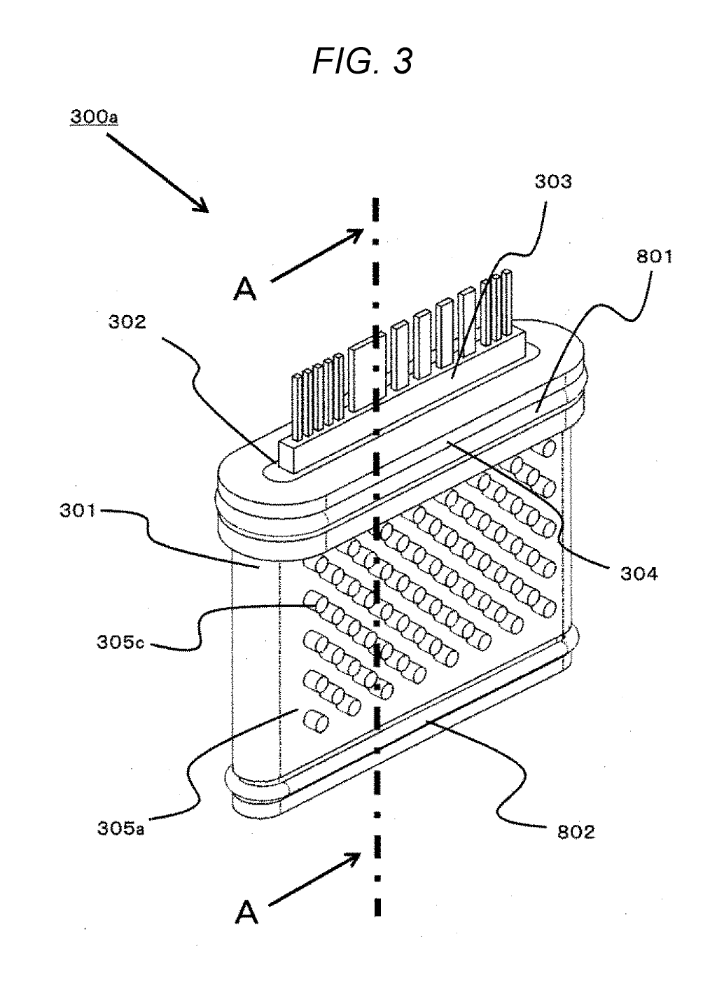

FIG. 3 is a perspective view of the power semiconductor module 300a according to the present embodiment. Since the power semiconductor modules 300b and 300c have similar structures to the power semiconductor module 300a, description thereof will be omitted. FIG. 4 is a cross-sectional view of the power semiconductor module 300a, assembled to the flow path forming body 200, cut from an arrow direction taken along an A-A cross section illustrated in FIG. 3.

A circuit portion of the power semiconductor module 300a includes a power semiconductor element (IGBT, diode, and the like) included in a series circuit, a conductor member, an AC terminal, a DC positive terminal, a DC negative terminal, and the like. The power semiconductor element and the like are sealed with a resin material and form a sealing body 303.

The sealing body 303 is inserted into an insertion port 302 of a module case 301 via insulating paper and the like. The sealing body 303 is bonded to an inner wall of the module case 301. The module case 301 includes a first heat dissipation unit 305a and a second heat dissipation unit 305b of which areas are larger than the side surface, and the first heat dissipation unit 305a and the second heat dissipation unit 305b face each other. In the sealing body 303, the power semiconductor element (IGBT, diode, and the like) is arranged to be faced to the first heat dissipation unit 305a and the second heat dissipation unit 305b. In the present embodiment, heat dissipation fins 305c are arranged in the first heat dissipation unit 305a and the second heat dissipation unit 305b. Furthermore, it is not necessary for the heat dissipation fin 305c to have a tubular shape, and the heat dissipation fin 305c may have another shape, or it is possible that the first heat dissipation unit 305a and the second heat dissipation unit 305b do not include the heat dissipation fins 305c.

As illustrated in FIG. 4, the flow path forming body 200 contains the power semiconductor module 300a and forms the flow path 400 through which the refrigerant flows. In addition, the flow path forming body 200 forms a first opening 401 which communicates one surface 400a of the flow path forming body 200 with the flow path 400.

The power semiconductor module 300a form first sealing surfaces 307 formed along an insertion direction from the first opening 401 to the flow path 400 and facing to each other. A first groove 306 to assemble a first sealing member 801 is provided in the module case 301. In the first groove 306, the first sealing surfaces 307 are formed which are formed along the insertion direction from the first opening 401 of the flow path forming body 200 to the flow path 400 and face each other. In the present embodiment, the first sealing surface 307 is formed in the first groove 306. However, the first sealing surface 307 may be formed on the other surface facing to the flow path forming body without providing the first groove 306.

In addition to the first sealing surface 307, in the power semiconductor module 300a, second sealing surfaces 309 are formed which are formed along the insertion direction from the first opening 401 of the flow path forming body 200 to the flow path 400 and face each other. In the present embodiment, a second groove 308 is formed on the opposite side of the first sealing surface 307 as sandwiching the first heat dissipation unit 305a and the second heat dissipation unit 305b which are heat dissipation surfaces of the power semiconductor module 300a and the heat dissipation fins 305c therebetween. The second sealing member 802 is arranged in the second groove 308. In the second groove 308, the second sealing surfaces 309 are formed which are formed along the insertion direction from the first opening 401 of the flow path forming body 200 to the flow path 400 and face each other.

A first projecting portion 304 is formed to be projected from the first heat dissipation unit 305a and the second heat dissipation unit 305b and functions as a flange. In addition, the first groove 306 is formed in a part of the first projecting portion 304 so that the first groove 306 is longer than the second groove 308.

The first sealing member 801 ensures watertightness by having contact with the first sealing surface 307 and the flow path forming body 200. In the present embodiment, the first sealing surface 307 is formed in the first groove 306. However, other surface facing to the flow path forming body such as a side surface of the first projecting portion 304 may be directly formed as the first sealing surface 307 without providing the first groove 306. In the present embodiment, the first sealing member 801 is assembled to the power semiconductor module 300a. However, the first sealing member 801 may be assembled to the flow path forming body 200.

The second sealing member 802 ensures watertightness by having contact with the second sealing surface 309 and the flow path forming body 200. In the present embodiment, the second sealing surface 309 is formed in the second groove 308. However, the second sealing surface 309 may be formed on the other surface facing to the flow path forming body without providing the second groove 308. In the present embodiment, the second sealing member 802 is assembled to the power semiconductor module 300a. However, the first sealing member 801 may be assembled to the flow path forming body 200. By providing the second sealing member 802, as illustrated in FIG. 4, a structure can be obtained in which a refrigerant does not flow to a power semiconductor module bottom surface 310.

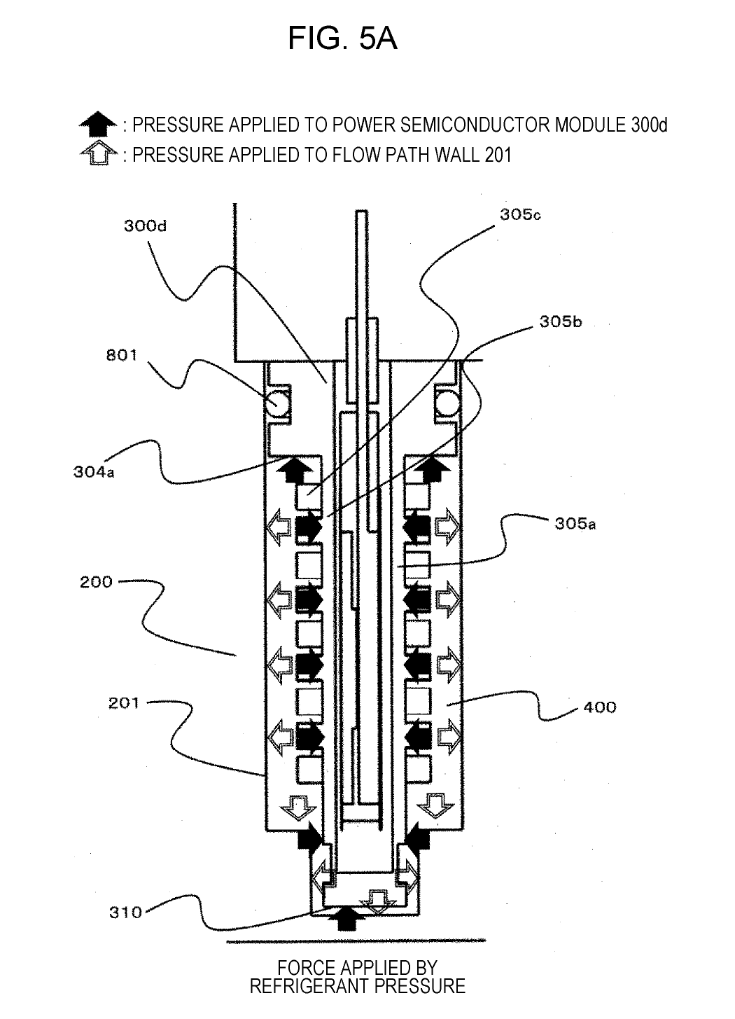

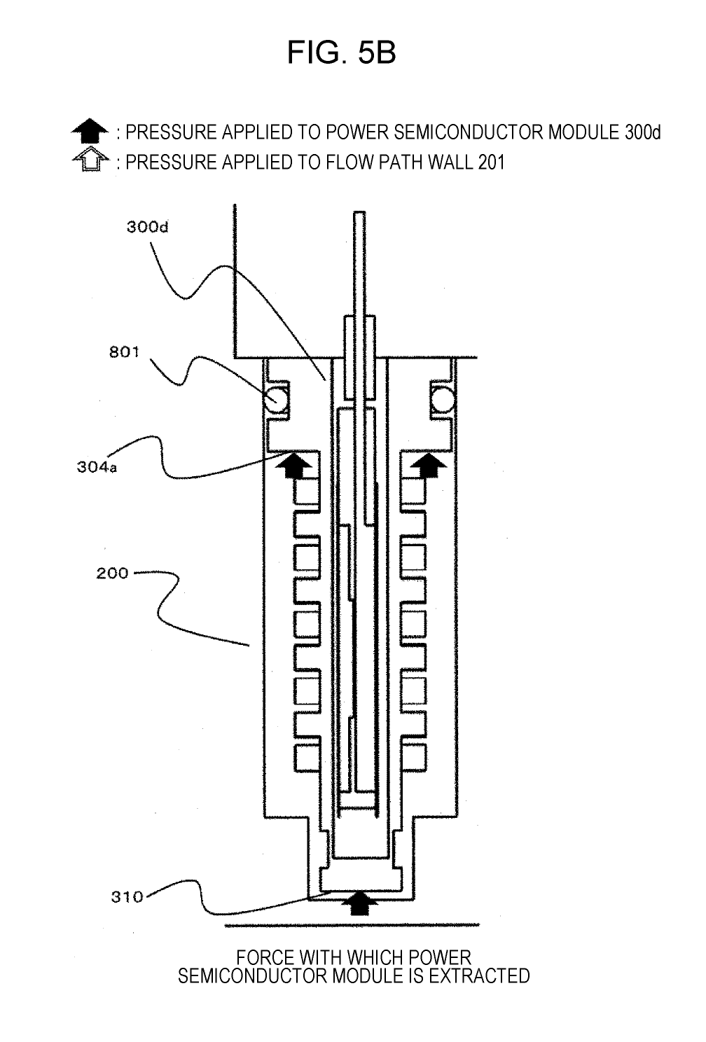

FIG. 5(a) is a diagram for explaining a refrigerant pressure among forces applied to a power semiconductor module 300d in a case where the second sealing member 802 is not provided as a comparative example. FIG. 5(b) is a diagram for explaining a force, with which the power semiconductor module 300d is extracted from the flow path forming body 200, among the forces applied to the power semiconductor module 300d in a case where the second sealing member 802 is not provided as the comparative example.

Fluid in a sealed container has properties such that the same amount of an internal force is perpendicularly applied to each of all pixels in a unit area of all the surfaces of the container when the force is applied at a single point, regardless of the shape of the container. In a case where the power semiconductor module 300d to which the second sealing member 802 is not assembled is assembled to the flow path forming body 200 and the flow path 400 is filled with the refrigerant, as illustrated in FIG. 5(a), the refrigerant flows to the power semiconductor module bottom surface 310. Therefore, the same amount of perpendicular force is applied to each surface of the power semiconductor module bottom surface 310 in addition to the flow path side wall 304a of the first projecting portion 304, the first heat dissipation unit 305a, the second heat dissipation unit 305b, the heat dissipation fins 305c, and the flow path wall 201 of the flow path forming body 200.

If the forces applied to these surfaces are added, as illustrated in FIG. 5(b), in the power semiconductor module 300d, the force is applied to the flow path side wall 304a and the power semiconductor module bottom surface 310 along the direction of extraction from the flow path forming body 200.

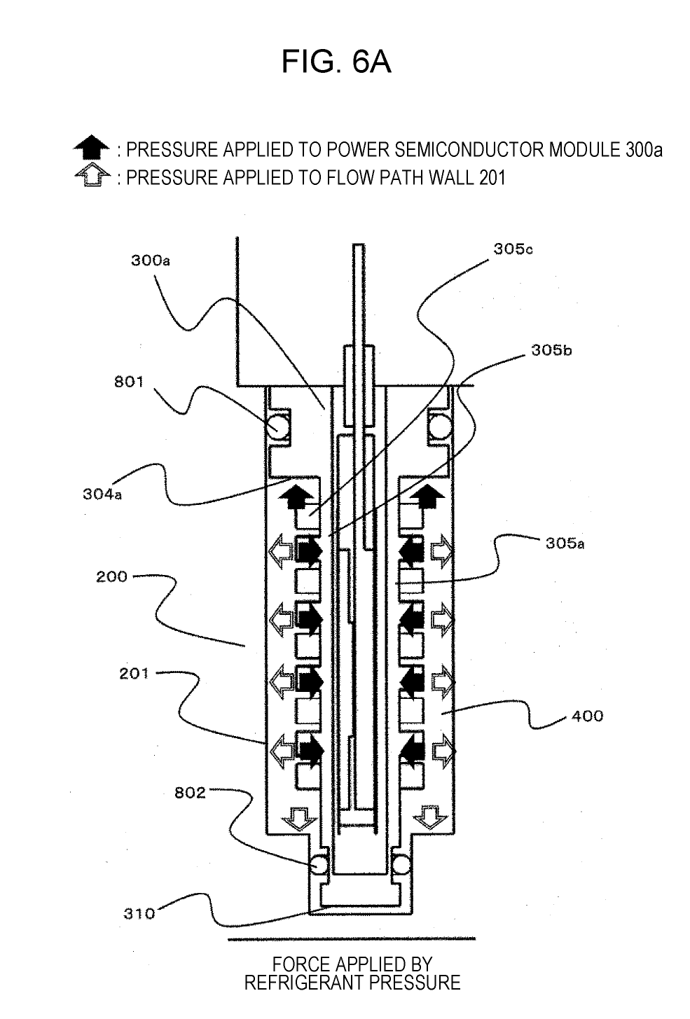

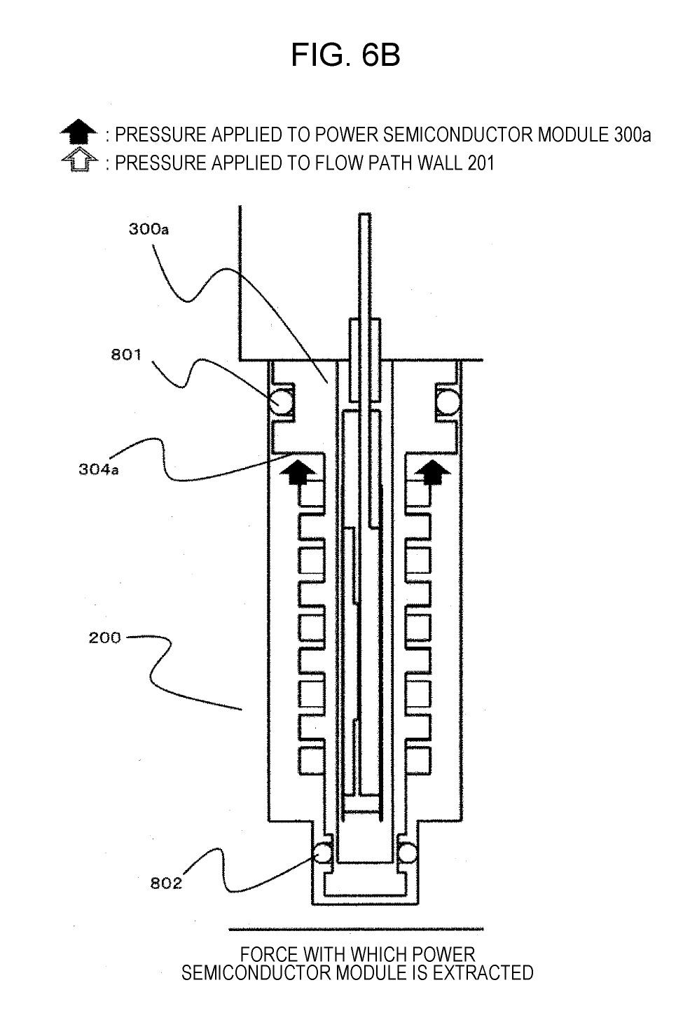

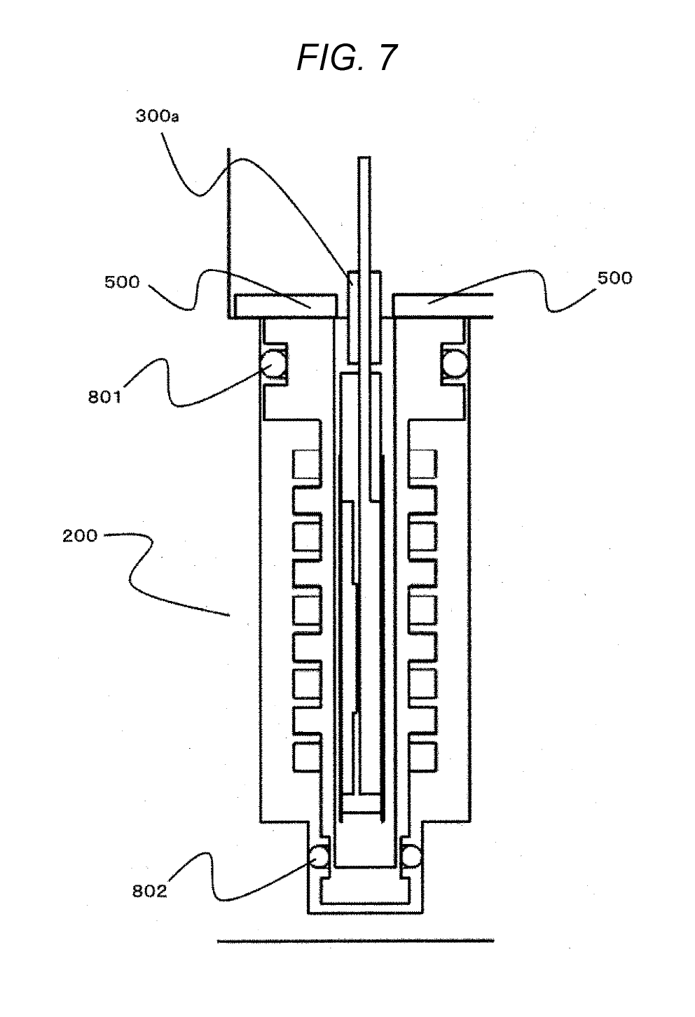

FIG. 6(a) is a diagram for explaining a refrigerant pressure among forces applied to the power semiconductor module 300a according to the present embodiment. FIG. 6(b) is a diagram for explaining a force, with which the power semiconductor module 300a is extracted from the flow path forming body 200, among the forces applied to the power semiconductor module 300a according to the present embodiment. FIG. 7 is a cross-sectional view in which the fixing plate 500 is provided on the flow path forming body 200.

In a case where the power semiconductor module 300a to which the second sealing member 802 is assembled is assembled to the flow path forming body 200 and the flow path 400 is filled with the refrigerant, as illustrated in FIG. 6(a), the refrigerant does not flow to the power semiconductor module bottom surface 310. Therefore, the same amount of perpendicular force is applied to each of the flow path side wall 304a, the first heat dissipation unit 305a, the second heat dissipation unit 305b, the heat dissipation fins 305c, and the flow path wall 201. If the forces applied to these surfaces are added, as illustrated in FIG. 6(b), in the power semiconductor module 300a, the force is applied to the flow path side wall 304a along the direction of the extraction from the flow path forming body 200.

In comparison between FIGS. 5 and 6, it is found that the force for the extraction from the flow path forming body 200 applied to the power semiconductor module 300d to which the second sealing member 802 is not assembled is larger than that applied to the power semiconductor module 300a to which the second sealing member 802 is assembled according to the present embodiment. Therefore, as illustrated in FIG. 7, an increase in the thickness of the fixing plate 500 provided to prevent the power semiconductor module 300a from being exposed is reduced, and it is not necessary to use an expensive material with high rigidity. There is a case where the fixing plate 500 becomes unnecessary.

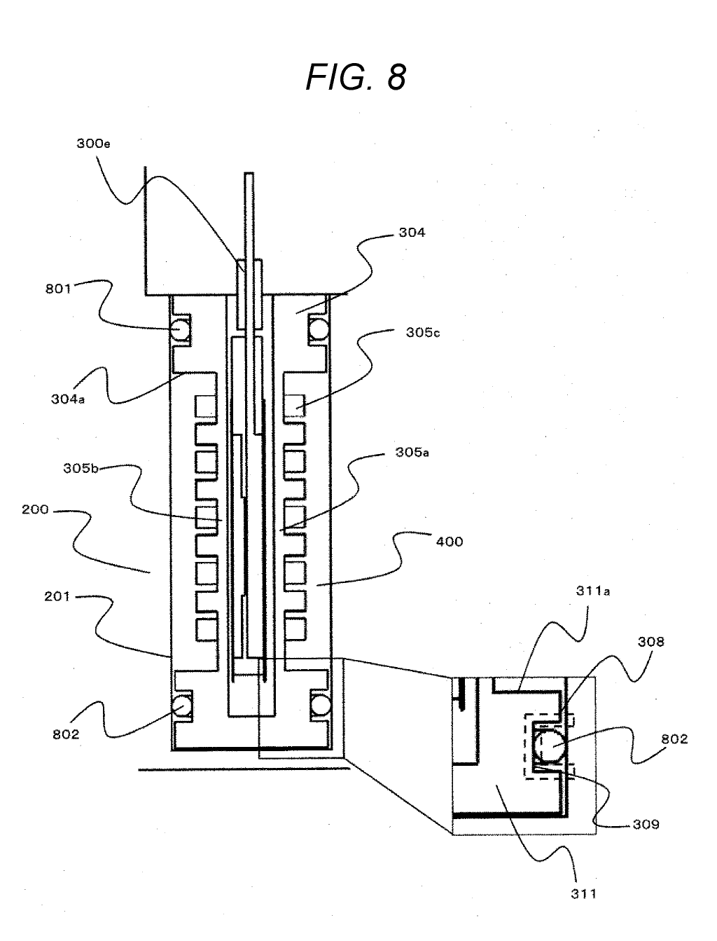

FIG. 8 is a diagram for explaining a power semiconductor module 300e including a second projecting portion 311. In the present embodiment, the first projecting portion 304 is formed in the power semiconductor module 300a. However, the second projecting portion 311 may be provided in addition to the first projecting portion 304 as illustrated in FIG. 8.

At this time, as illustrated in FIG. 8, the second groove 306 and the first sealing surface 307 for assembling the second sealing member 802 may be provided on an outer periphery of the second projecting portion 311.

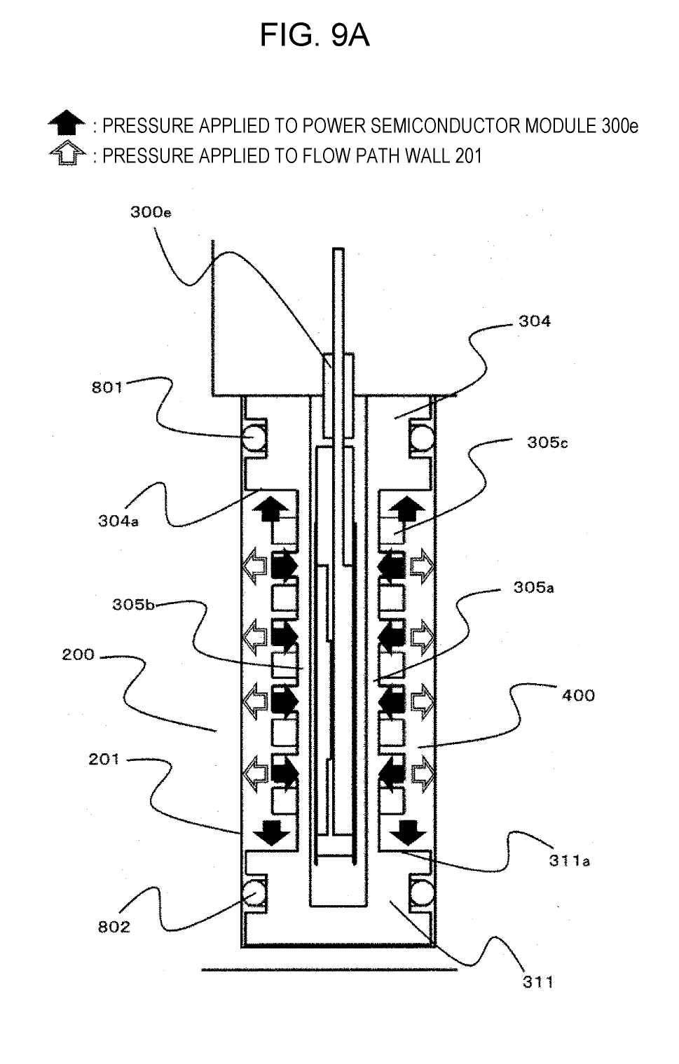

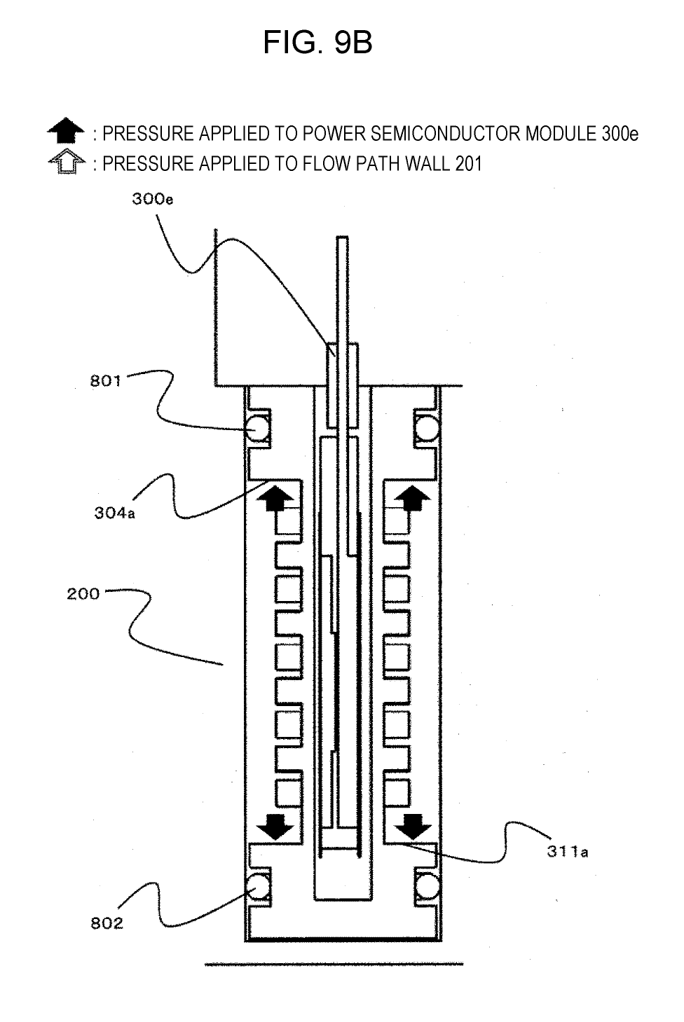

FIG. 9(a) is a diagram for explaining a refrigerant pressure among forces applied to the power semiconductor module 300e including the second projecting portion 311. FIG. 9(b) is a diagram for explaining a force, with which the power semiconductor module 300a is extracted from the flow path forming body 200, among the forces applied to the power semiconductor module 300e including the second projecting portion 311.

In a case where the power semiconductor module 300e in which the second projecting portion 311 is formed is assembled to the flow path forming body 200 and the flow path 400 is filled with the refrigerant, as illustrated in FIG. 9(a), the same amount of perpendicular force is applied to each of the flow path side wall 304a, the first heat dissipation unit 305a, the second heat dissipation unit 305b, the heat dissipation fins 305c, the flow path wall 201, and a flow path side wall 311a on the side of the second projecting portion 311. If the forces applied to these surfaces are added, as illustrated in FIG. 9(b), in the power semiconductor module 300e, the force is applied to the flow path side walls 304a and 311a.

At this time, as the area of the flow path side wall 311a is closer to the area of the flow path side wall 304a, in the power semiconductor module 300e, the force applied to the flow path side wall 304a on the side of the first projecting portion along the direction of the extraction from the flow path forming body 200 is reduced. In other words, the rigidity of the fixing plate 500 to fix the power semiconductor module 300e can be lowered since the force applied to the flow path side wall 304a is reduced, and an increase in size and cost of the fixing plate 500 can be prevented.

Furthermore, in a case where the area of the flow path side wall 311a is the same as the area of the flow path side wall 304a, the force applied to the flow path side wall 311a is the same as the force applied to the flow path side wall 304a. That is, since a resultant force of the force applied to the flow path side wall 311a and the force applied to the flow path side wall 304a is zero, the fixing plate 500 can be made unnecessary.

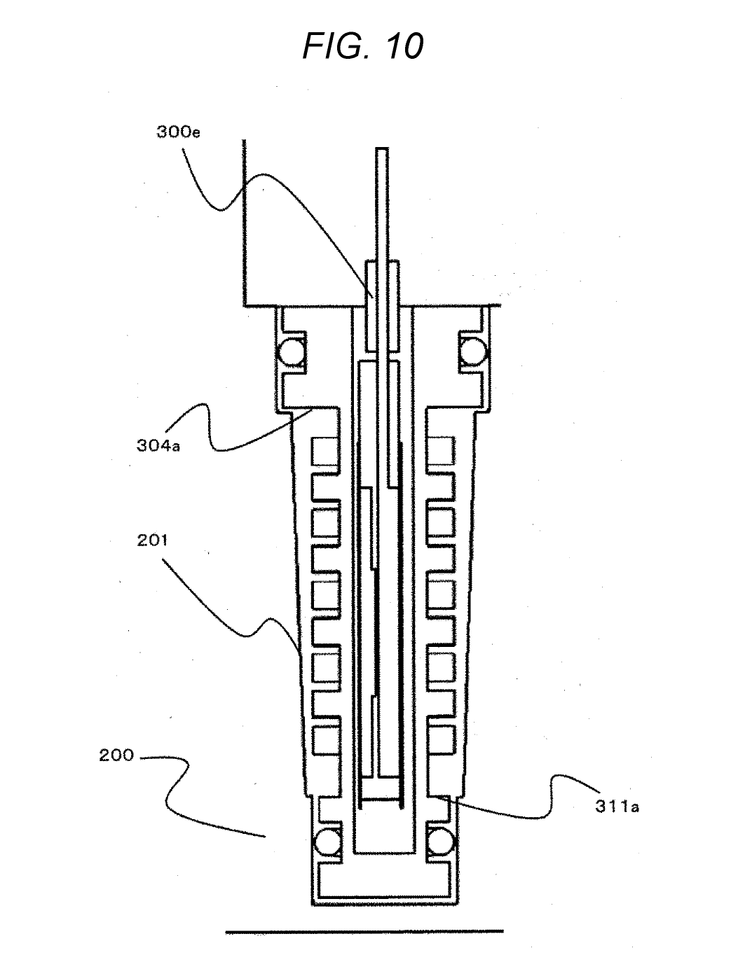

FIG. 10 is a cross-sectional view of an embodiment in which the flow path wall 201 of the flow path forming body 200 has a tapered shape.

In a case where the flow path forming body 200 is formed, for example, by die casting, to remove a mold after the material of the flow path forming body 200 is cured, the flow path wall 201 of the flow path forming body 200 has a tapered shape as illustrated in FIG. 10.

However, as illustrated in FIG. 10, this only causes reduction in the area of the flow path side wall 311a to be smaller than the area of the flow path side wall 304a, and the force applied to the flow path side wall 304a along the direction of the extraction of the power semiconductor module 300e from the flow path forming body 200 can be reduced.

Therefore, even if the flow path wall 201 of the flow path forming body 200 has a tapered shape, the rigidity of the fixing plate 500 to fix the power semiconductor module 300e can be lowered since the force applied to the flow path side wall 304a is reduced, and the fixing plate 500 of the power semiconductor module can be prevented from being enlarged.

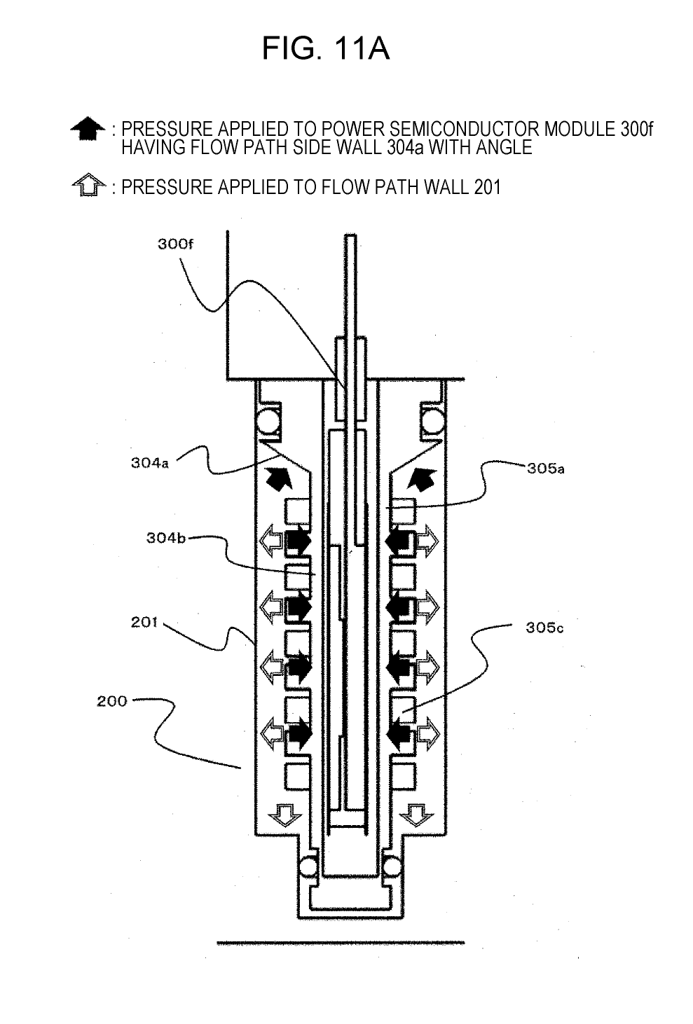

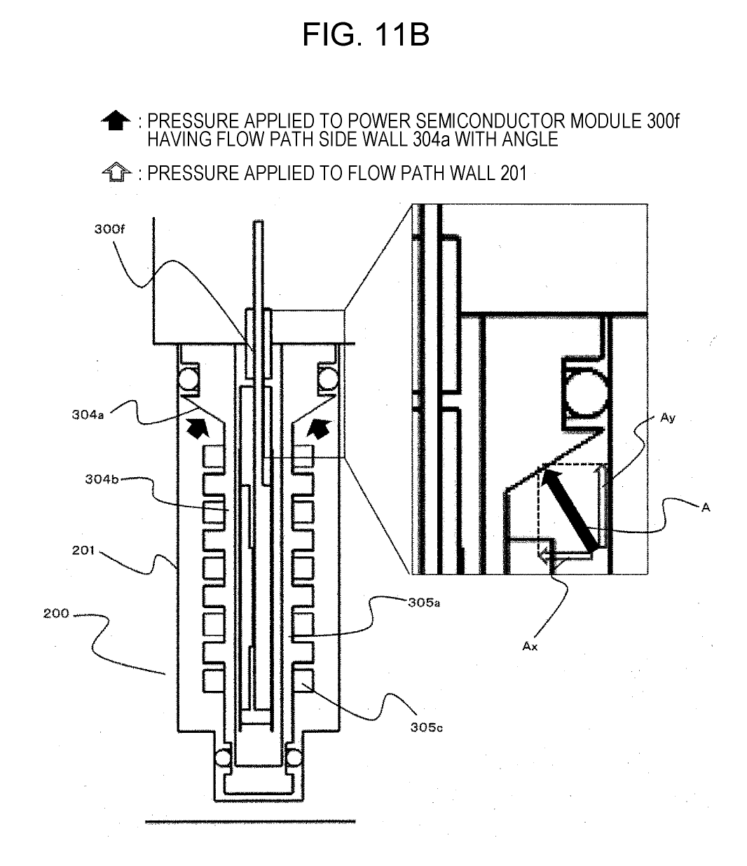

FIG. 11(a) is a diagram for explaining a refrigerant pressure among forces applied to a power semiconductor module 300f in which the flow path side wall 304a has an obtuse angle against the first heat dissipation unit 305a and the second heat dissipation unit 305b. FIG. 11(b) is a diagram for explaining a force, with which the power semiconductor module 300a is extracted from the flow path forming body 200, among the forces applied to the power semiconductor module 300f in which the flow path side wall 304a has an obtuse angle against the first heat dissipation unit 305a and the second heat dissipation unit 305b.

As illustrated in FIG. 11(a), it is not necessary for the flow path side wall 304a according to the present embodiment to form a plane perpendicular to the flow path wall 201 or the first heat dissipation unit 305a and the second heat dissipation unit 305b, and a plane having an angle relative to the flow path wall 201 or the first heat dissipation unit 305a and the second heat dissipation unit 305b may be formed. To have an angle means, for example, a case where an obtuse angle is formed between the flow path side wall 304a and the first heat dissipation unit 305a and the second heat dissipation unit 305b.

In a case where the power semiconductor module 300f of which the flow path side wall 304a has an angle is assembled to the flow path forming body 200 and the flow path 400 is filled with the refrigerant, as illustrated in FIG. 11(a), the same amount of perpendicular force is applied to each of the flow path side wall 304a, the first heat dissipation unit 305a, the second heat dissipation unit 305b, the heat dissipation fins 305c, and the flow path wall 201 of the flow path forming body 200. If the forces applied to these surfaces are added, as illustrated in FIG. 11(b), in the power semiconductor module 300f, the force is applied to the flow path side wall 304a along the direction of the extraction from the flow path forming body 200.

As illustrated in FIG. 11(b), when a force applied to the flow path side wall 304a is discomposed, the force A turns to be a force Ax and a force Ay. At this time, the force acting in the direction in which the power semiconductor module 300f is extracted from the flow path forming body 200 is the force Ay obtained by discomposing the force A applied to the flow path side wall 304a. Since the discomposed force Ay is smaller than the force A, the force acting in the direction in which the power semiconductor module 300f is extracted from the flow path forming body 200 is reduced.

That is, in a case where the flow path side wall 304a forms a plane having an angle (for example, obtuse angle) relative to the flow path wall 201, or the first heat dissipation unit 305a and the second heat dissipation unit 305b, the force acting in the direction of the extraction from the flow path forming body 200 can be reduced.

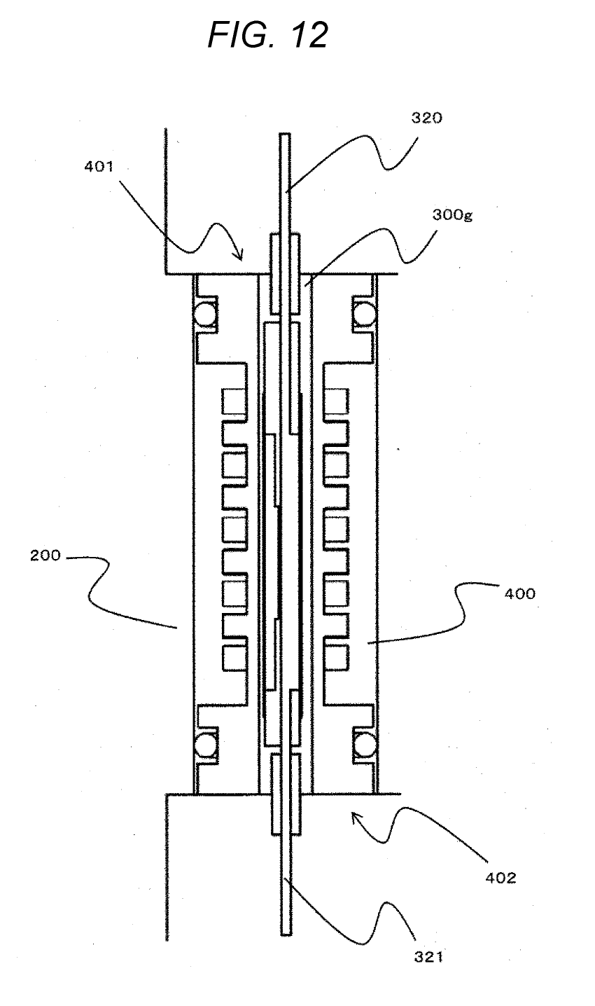

FIG. 12 is a cross-sectional view for explaining a power semiconductor module 300g having a first terminal 320 and a second terminal 321.

In the flow path forming body 200, a second opening 402 different from the first opening 401 may be formed. At this time, the second opening 402 is formed on the surface of the flow path forming body 200 different from the first opening 401, and the second opening 402 is formed to communicate one surface of the flow path forming body 200 with the flow path 400.

The flow path forming body 200 having the second opening 402 different from the first opening 401 contains the power semiconductor module 300g in which the first terminal 320 is projected from the first opening 401 and the second terminal 321 is projected from the second opening 402 and forms the flow path 400 through which the refrigerant flows. The principle illustrated in FIGS. 9(a) and 9(b) is applied to FIG. 12, and even in a case where the first terminal 320 and the second terminal 321 are respectively projected from two surfaces, the force acting in the direction of the extraction from the flow path forming body 200 can be reduced.

### REFERENCE SIGNS LIST

100 power converter
200 flow path forming body
200a flow path forming body lower surface
200b flow path forming body upper surface
210IN refrigerant inflow pipe
210OUT refrigerant outflow pipe
211IN refrigerant inflow port
211OUT refrigerant outflow port
220 casing lower cover
230 capacitor module
240 bus bar assembly
250N DC input bus bar
250P DC input bus bar
260 circuit board
270 casing upper cover
300a power semiconductor module
300b power semiconductor module
300c power semiconductor module
300d power semiconductor module
300e power semiconductor module
301 module case
302 insertion port
303 sealing body
304 first projecting portion
304a flow path side wall
305a first heat dissipation unit
305b second heat dissipation unit
305c heat dissipation fin
306 first groove
307 first sealing surface
308 second groove
309 second sealing surface
310 power semiconductor module bottom surface
311 second projecting portion
311a flow path side wall
320 first terminal
321 second terminal
400 flow path
400a one surface
401 first opening
402 second opening
500 fixing plate
801 first sealing member
802 second sealing member

1. A power converter comprising:
a power semiconductor module; and
a flow path forming body configured to contain the power semiconductor module and form a flow path through which a refrigerant flows, wherein
the flow path forming body forms a first opening which communicates one surface of the flow path forming body with the flow path, and
the power semiconductor module forms a first sealing surface which is formed along an insertion direction of the power semiconductor module into the flow path and faces the flow path forming body and a second sealing surface which is formed along the insertion direction and faces the flow path forming body.

2. The power converter according to claim 1, comprising:
a first sealing member having contact with the flow path forming body and arranged on the side of the first sealing surface; and
a second sealing member having contact with the flow path forming body and arranged on the side of the second sealing surface.

3. The power converter according to claim 1, wherein
the flow path forming body forms a second opening which is formed on a surface of the flow path forming body different from the first opening and communicates one surface of the flow path forming body with the flow path, and
the power semiconductor module includes a first terminal projected from the first opening and a second terminal projected from the second opening.

4. The power converter according to claim 1, wherein
the power semiconductor module includes a main body forming a heat dissipation surface and a first projecting portion which is projected from the main body and forms the first sealing surface on a top end surface of the projection.

5. The power converter according to claim 4, wherein
the power semiconductor module includes a second projecting portion which is projected from the main body and forms the second sealing surface on the top end surface of the projection.
